(19) United States
(12) Patent Application Publication
(10) Pub. No.: US 2008/0106867 A1
(43) Pub. Date: May 8, 2008

(54) FAN MOTOR DEVICE AND ELECTRONIC APPARATUS

(75) Inventors: Yoshihiro Abe, Kanagawa (JP); Hideo Magario, Ibaraki (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/748,746

(22) Filed: May 15, 2007

(30) Foreign Application Priority Data
May 29, 2006 (JP) 2006-147615

(51) Int. Cl. H05K 7/20; F04D 29/42

(52) U.S. Cl. 361/695; 415/206

(57) ABSTRACT

A fan motor device includes a multi-blade portion that rotates together with a rotor portion of a motor so as to take in air in an axial direction of the motor and discharge the air in a centrifugal direction, and a rib that supportively connects the multi-blade portion to the rotor portion. When the air is taken into the multi-blade portion due to the rotation of the rotor portion and the multi-blade portion, the rib generates negative pressure at a side thereof that is opposite to a side of the intake air.

### CROSS REFERENCES TO RELATED APPLICATIONS

The present invention contains subject matter related to Japanese Patent Application JP 2006-147615 filed in the Japanese Patent Office on May 29, 2006, the entire contents of which are incorporated herein by reference.

### BACKGROUND OF THE INVENTION

1. Field of the Invention

The present invention relates to a fan motor device that has a multi-blade portion that rotates together with a rotor portion of a motor to take in air in an axial direction of a rotary shaft and discharge the air in a centrifugal direction. The present invention also relates to an electronic apparatus equipped with such a fan motor device.

2. Description of the Related Art

Japanese Unexamined Patent Application Publication No. 2005-93604 discloses a typical example of an electronic apparatus, such as a computer or an image display apparatus, which employs a fan motor device for cooling an electronic component, such as a central processing unit (CPU), disposed inside the apparatus. In particular, blower fan devices that are configured to take in air in an axial direction of a rotary shaft of a multi-blade portion and to discharge the air in a centrifugal direction are effective for electronic apparatuses that have a small housing. These blower fan devices can exhibit a cooling effect with good efficiency.

A typical fan motor device includes a motor having a stator portion and a rotor portion, and a multi-blade portion that rotates together with the rotor portion of the motor. The motor has a shaft that extends through a shaft bearing, and the rotor portion rotates about this shaft. To prevent the rotor portion from disengaging from the shaft bearing, pressure is applied to the rotor portion in the axial direction by means of a suction magnet or by offsetting the magnetic balance between a magnet of the rotor portion and a core.

### SUMMARY OF THE INVENTION

However, the use of a suction magnet for preventing the rotor portion from disengaging from the shaft bearing will result in an increased number of components in the fan motor device, which will become a setback to achieving compactness of the device as well as leading to higher costs. On the other hand, if pressure is to be applied to the rotor portion in the axial direction by offsetting the magnetic balance between the magnet of the rotor portion and the core, it will be difficult to apply a large magnitude of pressure to the rotor portion. Due to this reason, vibration can occur in the axial direction as the rotor portion rotates.

According to an embodiment of the present invention, there is provided a fan motor device which includes a multi-blade portion that rotates together with a rotor portion of a motor so as to take in air in an axial direction of the motor and discharge the air in a centrifugal direction, and a rib that supportively connects the multi-blade portion to the rotor portion. When the air is taken into the multi-blade portion due to the rotation of the rotor portion and the multi-blade portion, the rib generates negative pressure at a side thereof that is opposite to a side of the intake air.

According to another embodiment of the present invention, there is provided a fan motor device which includes a motor having a stator portion and a rotor portion, a multi-blade portion attached to the rotor portion of the motor, and a rib that supportively connects the multi-blade portion to the rotor portion. The stator portion includes a shaft bearing, a coil disposed around the shaft bearing, and a core having the coil wound therearound or supporting the coil. The rotor portion includes a rotary shaft extending into the shaft bearing, a case that rotates around the stator portion about the rotary shaft, and a magnet attached to the case so as to face the coil. The multi-blade portion takes in air in an axial direction of the rotary shaft and discharges the air in a centrifugal direction of the rotor portion. The rib has a surface of a convex shape at a side thereof that is opposite to a side of the intake air.

According to the aforementioned embodiments of the present invention, the rib for supportively connecting the multi-blade portion to the rotor portion rotates together with the rotor portion so that negative pressure is generated at the side of the rib that is opposite to the side of the intake air. Accordingly, pressure can be applied to the rotor portion and the multi-blade portion towards the opposite side of the intake side.

In other words, the rib is given an airfoil shape such that a surface thereof opposite to the intake side in the axial direction is convex. Accordingly, as the rotor portion rotates, the pressure underneath the lower surface (i.e. the side opposite to the intake side) of the rib becomes lower than the pressure above the upper surface (i.e. the intake side), whereby a downward pushing force acts on the rotor portion through the rib.

By providing an electronic apparatus with a fan motor device of this type, an electronic component provided within a main housing of the apparatus can be cooled efficiently. In addition, the rotor portion is prevented from vibrating at the time of rotation thereof within the main housing.

According to the aforementioned embodiments of the present invention, the rib of the fan motor device is given a shape that can generate negative pressure so that the rotor portion can be pulled towards the shaft bearing. Accordingly, a low-cost fan motor device that has low vibration in the axial direction can be provided without the use of a suction magnet, or without having to offset the magnetic balance between the magnet of the rotor portion and the core, or with having a combination of generating the negative pressure and offsetting the magnetic balance to impart a strong suction force to the rotor portion.

### BRIEF DESCRIPTION OF THE DRAWINGS

FIG. 1 is a schematic perspective view of a fan motor device according to a first embodiment of the present invention;

FIG. 2 is a schematic perspective diagram of a rotor portion and a multi-blade portion included in the fan motor device and includes a partial cutaway view of the multi- blade portion;

FIG. 3 schematically illustrates a cross section of one of ribs included in the fan motor device and the flow of air;

FIGS. 4A and 4B are a top plan view and a bottom plan view of the rotor portion and the multi-blade portion;

FIG. 5 is a cross-sectional view of the fan motor device according to the first embodiment; and

FIG. 6 schematically illustrates an electronic apparatus according to a second embodiment of the present invention, to which the fan motor device according to the first embodiment is applied.

### DESCRIPTION OF THE PREFERRED EMBODIMENTS

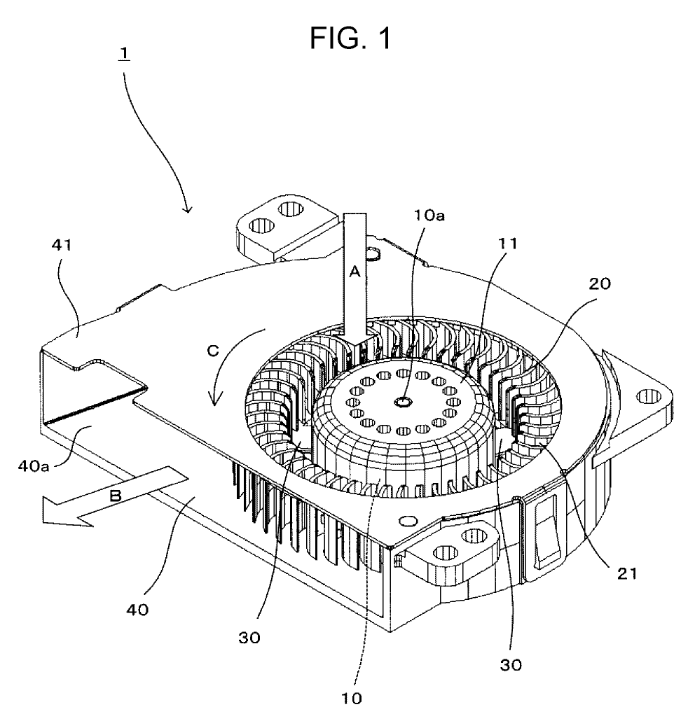

Embodiments of the present invention will now be described with reference to the drawings. FIG. 1 is a schematic perspective view of a fan motor device 1 according to a first embodiment of the invention. The fan motor device 1 mainly includes a multi-blade portion 20 and ribs 30. The multi-blade portion 20 rotates together with a rotor portion 11 of a motor 10 so as to take in air in a direction (indicated by an arrow A in FIG. 1) along a shaft 10a of the motor 10 and then discharge the air in a centrifugal direction (indicated by an arrow B in FIG. 1). The ribs 30 are provided for supportively connecting the multi-blade portion 20 to the rotor portion 11.

Specifically, in the first embodiment, the ribs 30 are configured to create negative pressure at a side thereof (lower side) opposite to the intake-air side (upper side) when the ribs 30 rotate around the shaft 10a together with the rotor portion 11.

Referring to FIG. 1, the motor 10 includes the rotor portion 11 that rotates together with the shaft 10a, and a stator portion (not shown) disposed within the rotor portion 11. The multi-blade portion 20 connected to the rotor portion 11 includes a plurality of blades 21 that are arranged radially along the outer periphery of the rotor portion 11. One side of each of the blades 21 that is directed in the rotational direction is concaved so that when the blade 21 rotates, the air is released sequentially in the centrifugal direction from the circumferential direction.

The stator portion of the motor 10 is fixed to a casing 40, and the upper outer periphery of the rotatable multi-blade portion 20 is covered with a cover 41. The cover 41 has an opening with appropriate dimensions for the rotor portion 11 and the multi-blade portion 20, so that air can be taken in through this opening. The intake air is delivered outward in the centrifugal direction by the blades 21 of the multi-blade portion 20 and is collected within a passage defined by the casing 40 and the cover 41 outside the multi-blade portion 20 so as to be finally released from an exhaust port 40a.

Accordingly, as the multi-blade portion 20 rotates in a direction indicated by an arrow C in FIG. 1, air is taken in through the opening of the cover 41 in the axial direction (arrow A) and is passed through a gap between the rotor portion 11 and the blades 21. The intake air sequentially travels through between the rotating blades 21 so as to flow outward. Finally, the centrifugally released air is collectively discharged from the exhaust port 40a of the casing 40.

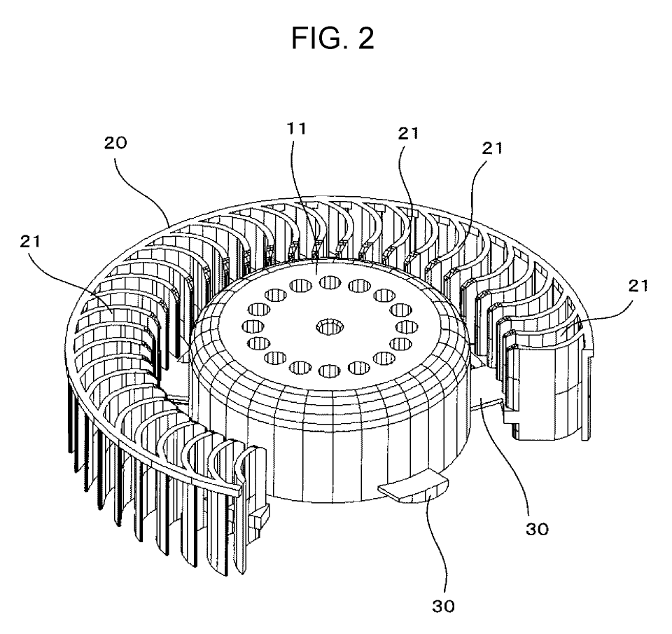

FIG. 2 is a schematic perspective diagram of the rotor portion 11 and the multi-blade portion 20 and includes a partial cutaway view of the multi-blade portion 20. In FIG. 2, the multi-blade portion 20 is partially cut away to exhibit the shape of the ribs 30 that supportively connect the multi-blade portion 20 to the rotor portion 11. The multi-blade portion 20 is supported by the outer periphery surface of the rotor portion 11 having a cylindrical shape through the plurality of ribs 30. The rotor portion 11, the ribs 30, and the multi-blade portion 20 are composed of resin and are formed integrally by injection molding.

The plurality of blades 21 included in the multi-blade portion 20 is arranged radially along the outer periphery of the rotor portion 11 at a predetermined pitch. Each of the blades 21 is curved such that one side thereof that is directed in the moving direction is concaved. Moreover, each blade 21 has its outer section inclined more in the moving direction than its inner section. Accordingly, when the multi-blade portion 20 rotates, the air flowing through between the blades 21 can be released in the centrifugal direction.

In the first embodiment, each of the ribs 30 that connect the multi-blade portion 20 to the rotor portion 11 is given an airfoil shape such that a side thereof (i.e. the surface facing downward) that is opposite to the intake-air side (i.e. the surface facing upward) is convex. In FIG. 2, the upper surface of each rib 30 is flat, whereas the lower surface thereof is convex.

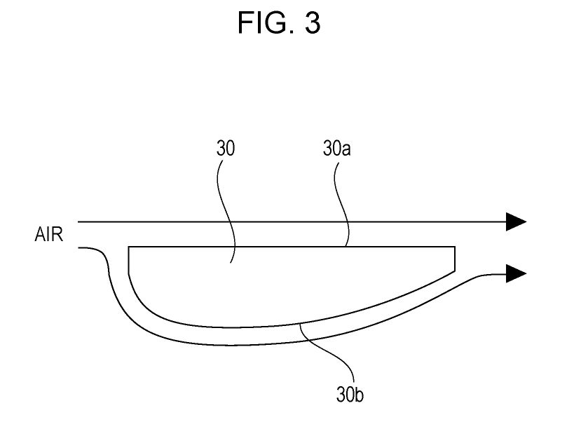

FIG. 3 schematically illustrates a cross section of one of the ribs 30 and the flow of air. The rib 30 having a flat upper surface 30a and a convex lower surface 30b as mentioned above creates a difference in path lengths of air flowing along the upper and lower surfaces 30a and 30b as the rib 30 rotates. In other words, the path length of air below the lower surface 30b is longer than that above the upper surface 30a, which implies that the air below the lower surface 30b flows faster than the air above the upper surface 30a. As a result, the pressure below the lower surface 30b becomes negative with respect to the pressure above the upper surface 30a. Accordingly, a downward force acts on the ribs 30, whereby the rotor portion 11 and the multi-blade portion 20 connected to the ribs 30 are pulled downward.

Since air is taken in from above in response to the rotation of the multi-blade portion 20, the reactive force of the intake air generally lifts the multi-blade portion 20 upward, that is, toward the intake side. In contrast, since a downward force is imparted on the ribs 30 in the first embodiment as described above, this downward force can counteract the force that tries to lift the multi-blade portion 20 towards the intake side. Accordingly, when the multi-blade portion 20 rotates, the multi-blade portion 20 takes in air while the multi-blade portion 20 itself is pulled downward, thereby reducing vibration occurring in the axial direction in response to the rotation.

Instead of the airfoil shape, the ribs 30 may be tabular in cross section. In that case, each of the ribs 30 may be mounted at an angle so that it is inclined downward in the moving direction. With this mounting angle, negative pressure can be created below the lower surface 30b of the rib 30. As a further alternative, the ribs 30 may have a combination of the airfoil shape and the aforementioned mounting angle.

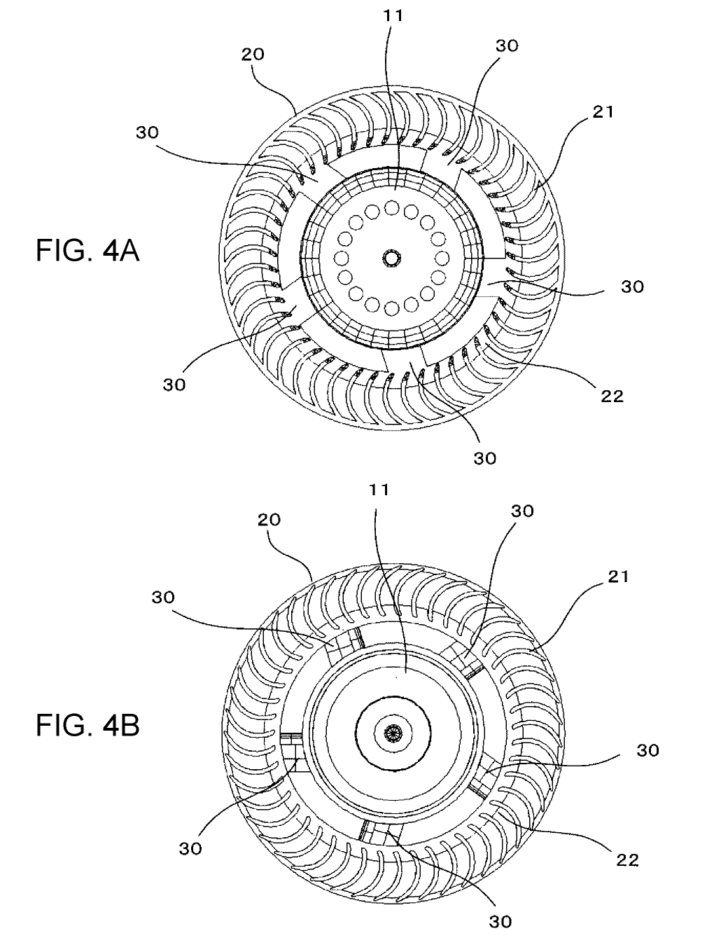

FIGS. 4A and 4B are a top plan view and a bottom plan view of the rotor portion 11 and the multi-blade portion 20. The ribs 30 that connect the multi-blade portion 20 to the rotor portion 11 are provided in plural numbers. In FIGS. 4A and 4B, five ribs 30 are provided in an equiangular fashion. The ribs 30 are plate-like members that connect the inner periphery surface of the multi-blade portion 20 to the outer periphery surface of the rotor portion 11, and each have a flat upper surface and a convex lower surface. Furthermore, the plurality of blades 21 included in the multi-blade portion 20 is mounted to a ring-shaped connector 22. This ring-shaped connector 22 is joined to the rotor portion 11 through the ribs 30.

The downward force acting on the ribs 30 increases with increasing number of the ribs 30. However, it may be necessary that an appropriate space be provided in front of each rib 30 as viewed in the moving direction. Moreover, the number and the strength of the ribs 30 should be determined so that they can securely support the multi-blade portion 20. To fulfill this, three to eight ribs 30 are preferable, but four to six ribs 30 are even more preferable.

Each of the ribs 30 provided between the rotor portion 11 and the multi-blade portion 20 may extend along a normal line relative to the tangent line of the outer periphery of the rotor portion 11 or may extend at a slight oblique angle with respect to the normal line. In the latter case where the ribs 30 extend obliquely, the upper and lower surfaces 30a, 30b of the ribs 30 can be increased in area so that even if there is only a small gap between the rotor portion 11 and the multi-blade portion 20, the negative pressure can be effectively produced by the ribs 30.

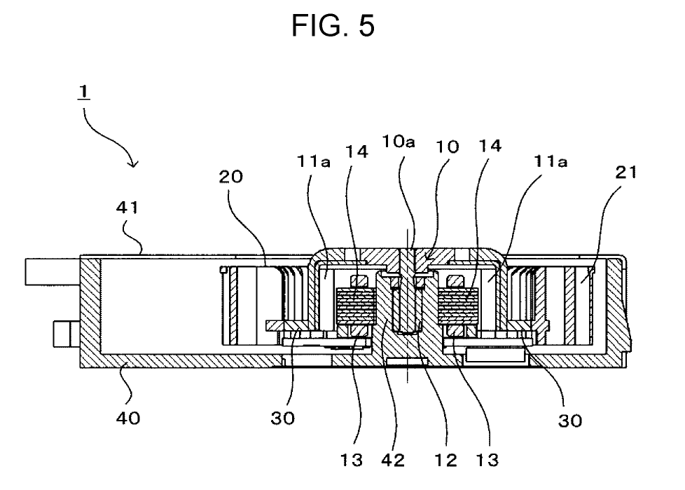

FIG. 5 is a cross-sectional view of the fan motor device 1 according to the first embodiment. The fan motor device 1 has a box-shaped container constituted by the casing 40 and the cover 41. The box-shaped container contains therein the motor 10 and the multi-blade portion 20.

The casing 40 has a cylindrical bearing mounting section 42 therein for holding a shaft bearing 12. Specifically, the shaft bearing 12 is fitted in the cylindrical bearing mounting section 42. The shaft bearing 12 has the shaft 10a extending therethrough, and the rotor portion 11 is attached to an end of the shaft 10a that is opposite to the insertion end thereof.

On the other hand, a core 13 having a coil 14 wound therearound is disposed around the bearing mounting section 42, thereby constituting the stator portion of the motor 10. The rotor portion 11 is disposed so as to surround this stator portion. A magnet 11a is attached to the inner periphery surface of the rotor portion 11 so as to face the coil 14 of the stator portion. Consequently, the rotor portion 11 can rotate around the stator portion through the shaft bearing 12 and the shaft 10a.

When electricity is applied to the coil 14, a magnetic line of force is produced in the core 13. Due to magnetic action between the core 13 and the magnet 11a, the rotor portion 11 rotates about the shaft 10a.

In the fan motor device 1, the multi-blade portion 20 is connected to the rotor portion 11 that is rotated by the motor 10. The multi-blade portion 20 has the plurality of radially arranged blades 21 that surround the rotor portion 11, and the rotor portion 11 and the multi-blade portion 20 are connected to each other through the ribs 30.

Accordingly, when the rotor portion 11 rotates, the multi-blade portion 20 connected to the rotor portion 11 through the ribs 30 also rotates, whereby the intake air can be delivered outward in the centrifugal direction by the blades 21.

Since the multi-blade portion 20 is surrounded by the casing 40 and the cover 41, the air pushed outward in the centrifugal direction by the blades 21 is guided towards the exhaust port 40a by being passed through the gap between the casing 40 and the cover 41. As a result, the air is discharged outward from the exhaust port 40a.

Accordingly, the multi-blade portion 20 of the fan motor device 1 rotates together with the rotor portion 11 so as to deliver air, taken in from above in the axial direction, outward in the centrifugal direction. Due to a reactive force generated in response to the intake of the air, the multi-blade portion 20 tries to lift itself upward. Because the shaft 10a attached to the rotor portion 11 is fitted to the shaft bearing 12 from above, there is an upward backlash in the rotor portion 11. In a typical fan motor device, this backlash and the upward lifting of the multi-blade portion occurring during the rotation induce vibration in the axial direction.

In contrast, according to the first embodiment, since negative pressure is produced underneath the ribs 30 in response to the rotation of the ribs 30, a force acts in a direction for suppressing the upward lifting of the rotating multi-blade portion 20. Thus, the vibration occurring in the axial direction due to the upward lifting of the rotating multi-blade portion 20 can be reduced.

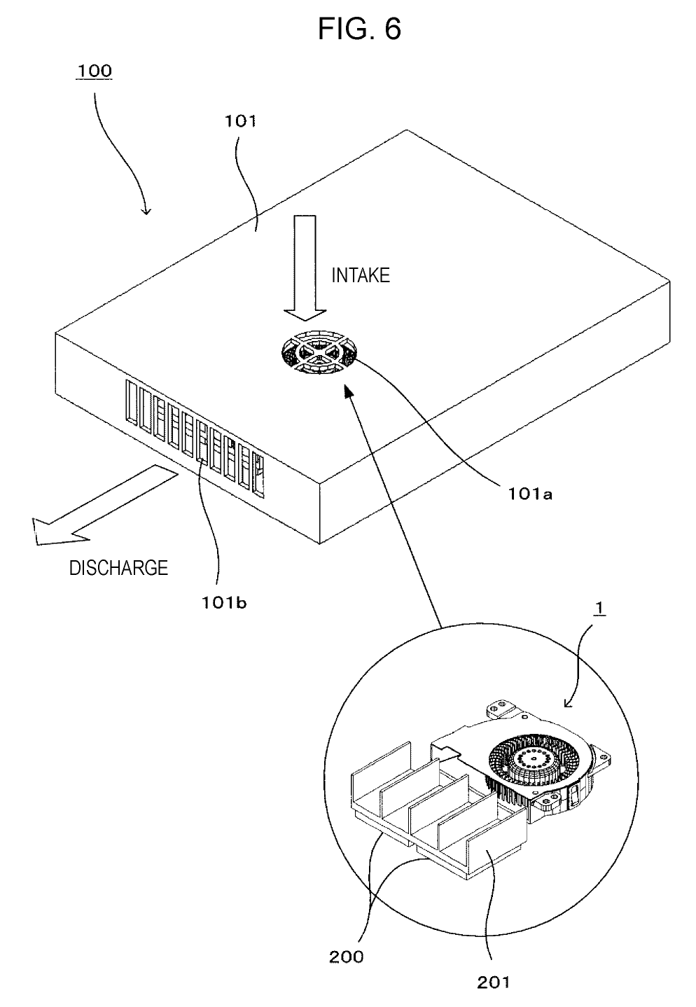

FIG. 6 schematically illustrates an apparatus according to a second embodiment of the present invention, to which the fan motor device 1 according to the first embodiment is applied. Specifically, this apparatus according to the second embodiment is an electronic apparatus 100 that has a main housing 101 containing an electronic component 200 and includes the fan motor device 1 according to the first embodiment. As described above, the fan motor device 1 is configured to take in air from above and to discharge the air in the centrifugal direction (lateral direction). Therefore, if the fan motor device 1 is to be installed in the main housing 101 of the electronic apparatus 100, an air intake port 101a is preliminarily provided on the upper side of the main housing 101 and an air exhaust port 101b is preliminarily provided on one of the lateral sides of the main housing 101.

For the electronic apparatus 100 whose main housing 101 has a small thickness, the fan motor device 1 that takes in air from above and discharges the air in the lateral direction is extremely effective. In the electronic apparatus 100, the electronic component 200, which is to be cooled by the fan motor device 1, is disposed between the fan motor device 1 and the air exhaust port 101b of the main housing 101.

If the electronic component 200 is, for example, a CPU, there will be a large amount of heat generated. In that case, the electronic component 200 usually has a heat sink 201 attached thereto. The air discharged from the fan motor device 1 cools the heat sink 201, thus enhancing the cooling efficiency of the electronic component 200. The air used for cooling is subsequently released outward from the air exhaust port 101b of the main housing 101.

Instead of being used for cooling a specific electronic component, the fan motor device 1 according to the first embodiment may be employed for suppressing a temperature increase within the main housing 101 or a temperature increase in the entire circuitry disposed within the main housing 101, depending on the structure of the electronic apparatus 100. Furthermore, the electronic apparatus 100 be equipped with the fan motor device 1 within the main ing 101 for the purpose of preventing air accumulation in the main housing 101. In that case, the main housing may be of a sealed type that does not have an air intake or an air exhaust port.

It should be understood by those skilled in the art various modifications, combinations, sub-combinations alterations may occur depending on design requirements other factors insofar as they are within the scope of appended claims or the equivalents thereof.

What is claimed is:

1. A fan motor device comprising:
a multi-blade portion that rotates together with a rotor portion of a motor so as to take in air in an axial direction of the motor and discharge the air in a centrifugal direction; and
a rib that supportively connects the multi-blade portion to the rotor portion, wherein when the air is taken into the multi-blade portion due to the rotation of the rotor portion and the multi-blade portion, the rib generates negative pressure at a side thereof that is opposite to a side of the intake air.

2. A fan motor device comprising:
a motor;
wherein the motor includes
a stator portion including a shaft bearing, a coil disposed around the shaft bearing, and a core having the coil wound therearound or supporting the coil, and
a rotor portion including a rotary shaft extending into the shaft bearing, a case that rotates around the stator portion about the rotary shaft, and a magnet attached to the case so as to face the coil,
a multi-blade portion attached to the rotor portion of the motor, the multi-blade portion taking in air in an axial direction of the rotary shaft and discharging the air in a centrifugal direction of the rotor portion; and
a rib that supportively connects the multi-blade portion to the rotor portion, wherein the rib has a surface of a convex shape at a side thereof that is opposite to a side of the intake air.

3. The fan motor device according to claim 2, wherein when the air is taken into the multi-blade portion due to the rotation of the rotor portion and the multi-blade portion, the rib generates negative pressure at the side thereof opposite to the side of the intake air.

4. The fan motor device according to claim 2, wherein the rib is provided within an inner periphery of the multi-blade portion.

5. The fan motor device according to claim 2, wherein the convex shape of the rib includes an airfoil shape.

6. An electronic apparatus comprising:
a main housing containing an electronic component; and
a fan motor device for cooling the electronic component disposed within the main housing,
wherein the fan motor device includes
a multi-blade portion that rotates together with a rotor portion of a motor so as to take in air in an axial direction of the motor and discharge the air in a centrifugal direction, and
a rib that supportively connects the multi-blade portion to the rotor portion, wherein when the air is taken into the multi-blade portion due to the rotation of the rotor portion and the multi-blade portion, the rib generates negative pressure at a side thereof opposite to a side of the intake air.
